(19) United States
(12) Patent Application Publication
(10) Pub. No.: US 2021/0311133 A1
(43) Pub. Date: Oct. 7, 2021

(54) INDOOR POSITION ESTIMATION APPARATUS, USER TERMINAL, INDOOR POSITION ESTIMATION METHOD, AND PROGRAM

(71) Applicant: NEC Corporation, Minato-ku, Tokyo (JP)

(72) Inventors: Kouji OOSUGI, Tokyo (JP); Tasuku YAMAGUCHI, Tokyo (JP)

(73) Assignee: NEC Corporation, Minato-ku, Tokyo (JP)

(21) Appl. No.: 17/265,021

(22) PCT Filed: Mar. 19, 2019
(86) PCT No.: PCT/JP2019/011460

§ 371 Date: Feb. 1, 2021

(30) Foreign Application Priority Data
Aug. 2, 2018 (JP) 2018-145940

(51) Int. Cl. G01R 33/02; G01C 21/28; G06N 20/00

(52) U.S. Cl. CPC G01R 33/02; G06N 20/00; G01C 21/28

(57) ABSTRACT

According to the present disclosure, there is provided an indoor position estimation apparatus (100) including: a first acquisition unit (111) that acquires a target magnetic pattern indicating a result obtained by repeatedly measuring an indoor magnetic field by a position estimation target including a magnetic sensor; a first extraction unit (112) that extracts predetermined frequency components from the target magnetic pattern; and an estimation unit (113) that obtains an estimation result of an indoor position of the position estimation target by inputting data on the extracted frequency components into an estimation model obtained by machine learning.

### TECHNICAL FIELD

The present disclosure relates to an indoor position estimation apparatus, a user terminal, an indoor position estimation method, and a program.

### BACKGROUND ART

In position estimation of an object in an outdoor area, a triangulation surveying technique using reception of radio waves from an artificial satellite such as global positioning system (GPS) is used. However, radio waves do not accurately reach an indoor area. As a result, it is difficult to use the technique in an indoor area. In position estimation of an object in an indoor area, a surveying method using radio wave communication used indoors such as Wifi or Bluetooth (registered trademark) low energy (BLE) is used. In the techniques, a radio wave transmitter needs to be provided inside and around a structure. However, depending on a shape of the structure and a purpose of appearance protection, in many cases, it is difficult to provide the radio wave transmitter.

For this reason, as a position estimation method that can be used indoors and does not require provision of a radio wave transmitter, Patent Document 1 discloses a position estimation technique using magnetic information measured by a magnetic sensor.

### RELATED DOCUMENT

### Patent Document

[Patent Document 1] Japanese Patent Application Publication No. 2013-210866

### SUMMARY OF THE INVENTION

### Technical Problem

However, the technique described in Patent Document 1 has problems that an influence of a geomagnetic field is most strongly represented as positioning magnetic information and that a positioning reference point deviation of the magnetic sensor called an offset deviation occurs. As a result, position estimation accuracy is insufficient.

The present disclosure provides a technique for improving position estimation accuracy in position estimation using magnetic information.

### Solution to Problem

According to the present disclosure, there is provided an indoor position estimation apparatus including: a first acquisition unit that acquires a target magnetic pattern indicating a result obtained by repeatedly measuring an indoor magnetic field by a position estimation target including a magnetic sensor; a first extraction unit that extracts predetermined frequency components from the target magnetic pattern; and an estimation unit that obtains an estimation result of an indoor position of the position estimation target by inputting data on the extracted frequency components into an estimation model obtained by machine learning.

Further, according to the present disclosure, there is provided an indoor position estimation method executed by a computer, the method including: a first acquisition step of acquiring a target magnetic pattern indicating a result obtained by repeatedly measuring an indoor magnetic field by a position estimation target including a magnetic sensor; a first extraction step of extracting predetermined frequency components from the target magnetic pattern; and an estimation step of obtaining an estimation result of an indoor position of the position estimation target by inputting data on the extracted frequency components into an estimation model obtained by machine learning.

Further, according to the present disclosure, there is provided a program causing a computer to function as: a first acquisition unit that acquires a target magnetic pattern indicating a result obtained by repeatedly measuring an indoor magnetic field by a position estimation target including a magnetic sensor; a first extraction unit that extracts predetermined frequency components from the target magnetic pattern; and an estimation unit that obtains an estimation result of an indoor position of the position estimation target by inputting data on the extracted frequency components into an estimation model obtained by machine learning.

Further, according to the present disclosure, there is provided a user terminal including: a magnetic sensor that measures an indoor magnetic field; an acquisition unit that acquires a target magnetic pattern indicating a result measured by the magnetic sensor; and a communication unit that transmits the target magnetic pattern to an indoor position estimation apparatus that estimates a position of the user terminal in an indoor area based on predetermined frequency components included in the target magnetic pattern.

Further, according to the present disclosure, there is provided an indoor position estimation apparatus including: a first acquisition unit that acquires a target magnetic pattern indicating a result obtained by repeatedly measuring an indoor magnetic field by a position estimation target including a magnetic sensor; a first extraction unit that extracts predetermined frequency components from the target magnetic pattern; and an estimation unit that obtains an estimation result of an indoor position of the position estimation target based on the extracted frequency components.

### Advantageous Effects of Invention

According to the present disclosure, it is possible to improve position estimation accuracy in position estimation using magnetic information.

### BRIEF DESCRIPTION OF THE DRAWINGS

The objective and other objectives, and features and advantages will be further clarified by preferred example embodiments to be described below and the accompanying drawings.

FIG. 1 is a diagram illustrating an example of a hardware configuration of an apparatus according to the present example embodiment.

FIG. 2 is a diagram illustrating an example of a functional block diagram of an indoor position estimation apparatus according to the present example embodiment.

FIG. 3 is a diagram illustrating an example of data processed by the indoor position estimation apparatus according to the present example embodiment.

FIG. 4 is a diagram illustrating an example of a functional block diagram of the indoor position estimation apparatus according to the present example embodiment.

FIG. 5 is a diagram illustrating an example of a functional block diagram of the indoor position estimation apparatus according to the present example embodiment.

FIG. 6 is a diagram illustrating an example of data processed by the indoor position estimation apparatus according to the present example embodiment.

FIG. 7 is a diagram illustrating an example of a functional block diagram of the indoor position estimation apparatus according to the present example embodiment.

FIG. 8 is a diagram illustrating an example of a functional block diagram of the indoor position estimation apparatus according to the present example embodiment.

FIG. 9 is a diagram illustrating an example of a functional block diagram of the indoor position estimation apparatus according to the present example embodiment.

FIG. 10 is a diagram illustrating an example of a functional block diagram of a positioning magnetic map creation system according to the present example.

FIG. 11 is a diagram for explaining a positioning label according to the present example.

FIG. 12 is a diagram for explaining a relationship between a positioning label and a positioning pattern according to the present example.

FIG. 13 is a diagram for explaining a relationship between a positioning label and a positioning pattern according to the present example.

FIG. 14 is a flowchart illustrating an example of a flow of processing in a preparation phase and a positioning phase according to the present example.

FIG. 15 is a diagram for explaining a relationship between a positioning label and a positioning pattern according to the present example.

FIG. 16 is a diagram for explaining contents of processing according to the present example.

### DESCRIPTION OF EMBODIMENTS

### First Example Embodiment

An indoor position estimation apparatus according to the present example embodiment estimates a position of a position estimation target based on a target magnetic pattern indicating a result obtained by repeatedly measuring an indoor magnetic field by the position estimation target including a magnetic sensor. The indoor position estimation apparatus according to the present example embodiment improves a position estimation accuracy by estimating the position of the position estimation target based on predetermined frequency components included in the target magnetic pattern. Hereinafter, details will be described.

First, an example of a hardware configuration of the indoor position estimation apparatus will be described. Each functional unit included in the indoor position estimation apparatus according to the present example embodiment is realized by any combination of hardware and software including a central processing unit (CPU) of a certain computer, a memory, a program loaded in the memory, a storage unit such as a hard disk that stores the program (a storage unit that can store a program stored in advance from when the indoor position estimation apparatus is shipped and a program downloaded from a storage medium such as a compact disc (CD) or a server on the Internet), and a network connection interface. It is understood by those skilled in the related art that various modifications may be made in the realization method and the apparatus.

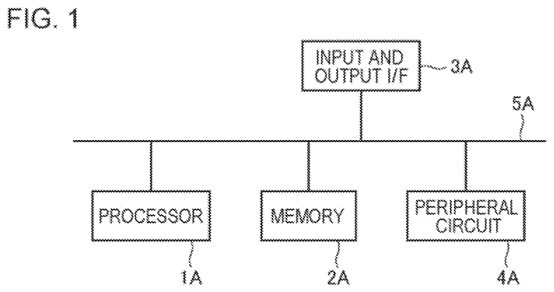

FIG. 1 is a block diagram illustrating a hardware configuration of the indoor position estimation apparatus according to the present example embodiment. As illustrated in FIG. 1, the indoor position estimation apparatus includes a processor 1A, a memory 2A, an input and output interface 3A, a peripheral circuit 4A, and a bus 5A. The peripheral circuit 4A includes various modules. The processing apparatus may not include the peripheral circuit 4A. Note that the indoor position estimation apparatus may be configured with a plurality of apparatuses physically separated from each other. In this case, each apparatus may have the above-described hardware configuration.

The bus 5A is a data transmission line through which the processor 1A, the memory 2A, the peripheral circuit 4A, and the input and output interface 3A transmit and receive data to and from each other. The processor 1A is, for example, an arithmetic processing device such as a CPU or a graphics processing unit (GPU). The memory 2A is, for example, a memory such as a random access memory (RAM) or a read only memory (ROM). The input and output interface 3A includes an interface that acquires information from an input device, an external device, an external server, an external sensor, and the like, an interface that outputs information to an output device, an external device, an external server, and the like. The input device includes, for example, a keyboard, a mouse, a microphone, and the like. The output device includes, for example, a display, a speaker, a printer, a mailer, and the like. The processor 1A can issue a command to each module and perform calculation based on calculation results of each module.

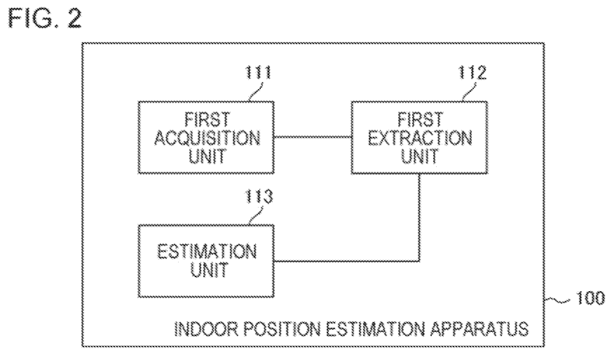

Next, a functional configuration of the indoor position estimation apparatus will be described. FIG. 2 illustrates an example of a functional block diagram of the indoor position estimation apparatus 100. As illustrated in FIG. 2, the indoor position estimation apparatus 100 includes a first acquisition unit 111, a first extraction unit 112, and an estimation unit 113.

The first acquisition unit 111 acquires a target magnetic pattern indicating a result obtained by repeatedly measuring an indoor magnetic field by the position estimation target including a magnetic sensor.

The magnetic sensor measures, for example, a strength of a magnetic field in directions of three axes. The target magnetic pattern indicates a temporal change of the strength of the measured magnetic field in each axis direction according to a movement of the position estimation target. The position estimation target is a communication apparatus having a communication function. The position estimation target is, for example, a user terminal that is carried by a user, and includes a smartphone, a mobile phone, a tablet terminal, a wearable terminal, an IoT terminal, and a portable game machine. On the other hand, the position estimation target is not limited thereto. The position estimation target may move according to walking of the user or a movement of a vehicle on which the user rides (for example, a bicycle, a car, a bus, a truck, a train). Further, in a case where the position estimation target is a self-traveling apparatus such as a robot, a drone, a carriage, or a car, the position estimation target itself may move.

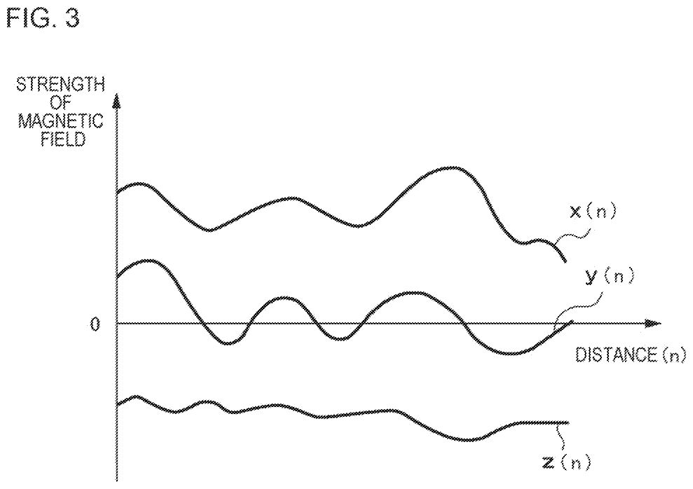

FIG. 3 illustrates an example of the target magnetic pattern. The target magnetic pattern illustrated in FIG. 3 indicates a result obtained by repeatedly measuring a strength of a magnetic field in each axis direction while the position estimation target is moving from an indoor nₛ position to an indoor nₑ position. In a graph of FIG. 3, a vertical axis indicates the strength of the magnetic field. The strength of the magnetic field on the vertical axis may be indicated in units of [A/m], or may be indicated by a value obtained by normalizing a value indicated in units of [A/m]. A horizontal axis indicates a movement distance n. The movement distance n indicates a movement distance from the nₛ position when the nₛ position is set as an origin. The movement distance can be calculated based on, for example, an elapsed time from when measurement is performed at the nₛ position and a general walking velocity. In FIG. 3, x(n) indicates the strength of the magnetic field in an x-axis direction at an n position, y(n) indicates the strength of the magnetic field in a y-axis direction at the n position, and z(n) indicates the strength of the magnetic field in a z-axis direction at the n position. Note that data of FIG. 3 is an image diagram and is not an actual measurement value.

Returning to FIG. 2, the first extraction unit 112 extracts predetermined frequency components from the target magnetic pattern by using a digital filter such as a bandpass filter. That is, the first extraction unit 112 extracts predetermined frequency components from each magnetic pattern by applying a bandpass filter to each magnetic pattern indicating a temporal change of the strength of the magnetic field in each axis direction. In the bandpass filter, for example, a stopband start end is 0.05 Hz, a passband start end is 0.1 Hz, a passband end is 0.8 Hz, and a stopband end is 1.0 Hz.

The estimation unit 113 obtains an estimation result of an indoor position of the position estimation target by inputting data related to the predetermined frequency components of the target magnetic pattern extracted by the first extraction unit 112 to an estimation model obtained by machine learning. The data related to the predetermined frequency components of the target magnetic pattern may be predetermined frequency components of the target magnetic pattern, or may be data indicating a feature of the predetermined frequency components of the target magnetic pattern.

Next, an advantageous effect of the indoor position estimation apparatus 100 according to the present example embodiment will be described.

The target magnetic pattern measured in an indoor area by the position estimation target includes a geomagnetic field, an offset deviation, a vibration caused by walking of a user who carries the position estimation target or rotation of wheels of a vehicle including the position estimation target, a bias error of the magnetic sensor, and an influence of a hard magnetic material contained in a structure. In a case where magnetic information displacement caused by a movement of the position estimation target (a temporal change in the strength of the magnetic field in each axis direction) is regarded as a signal waveform, the geomagnetic field is detected as an ultra-low frequency component. The offset deviation is detected as a DC component which does not change. The vibration caused by the movement of the position estimation target is detected as a frequency component associated with a period of the walking of the user or a period of the rotation of the wheels of the vehicle. The bias error may be ignored because the bias error is very small compared to the influence of the hard magnetic material.

For this reason, the digital filter such as a bandpass filter removes an ultra-low frequency band close to the DC component and a frequency band including a frequency equal to or higher than the frequency associated with the period of the walking of the user or the period of the rotation of the wheels of the vehicle, and extracts a frequency band between the frequency bands. Thus, a magnetic pattern that is dominantly influenced by the hard magnetic material contained in the structure is extracted. That is, noise components such as the geomagnetic field, the offset deviation, and the vibration caused by the movement of the position estimation target are reduced, and the magnetic pattern in which components of the hard magnetic material contained in the structure are dominant is extracted. The indoor position estimation apparatus 100 according to the present example embodiment performs position estimation by using the magnetic pattern extracted in this way. Therefore, it is possible to perform position estimation of the position estimation target with high accuracy.

In the present example embodiment, the noise components include components related to the geomagnetic field, the offset deviation, and the vibration caused by the movement of the position estimation target. On the other hand, the noise components are not limited thereto. The noise components may be a part of the above-mentioned components, or may further include other components.

### Second Example Embodiment

The indoor position estimation apparatus 100 according to the present example embodiment is different from the indoor position estimation apparatus 100 according to the first example embodiment, in that units for generating an estimation model to be used in position estimation by the estimation unit 113 are further included in addition to the configuration described in the first example embodiment. Hereinafter, details will be described. Other configurations are the same as in the first example embodiment.

An example of the hardware configuration of the indoor position estimation apparatus 100 according to the present example embodiment is the same as that of the first example embodiment.

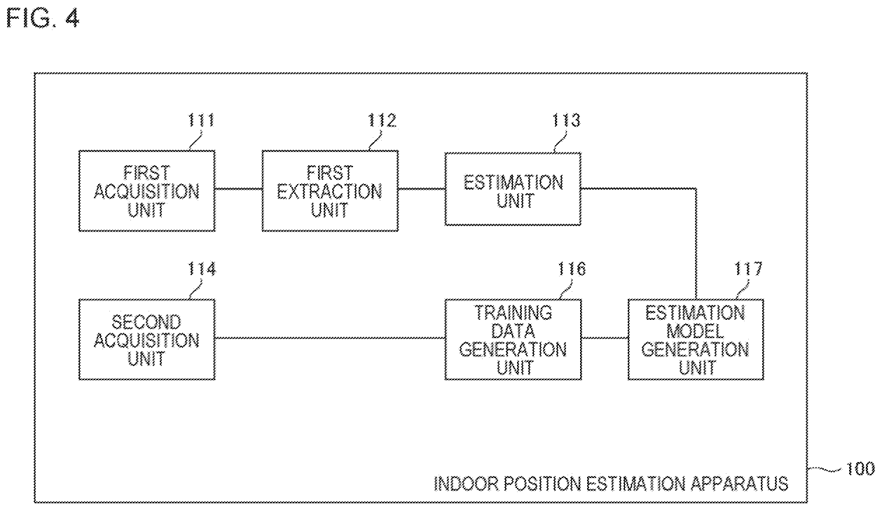

FIG. 4 illustrates an example of a functional block diagram of the indoor position estimation apparatus 100. As illustrated in FIG. 4, the indoor position estimation apparatus 100 includes a first acquisition unit 111, a first extraction unit 112, an estimation unit 113, a second acquisition unit 114, a training data generation unit 116, and an estimation model generation unit 117. The configurations of the first acquisition unit 111, the first extraction unit 112, and the estimation unit 113 are the same as those of the first example embodiment.

The second acquisition unit 114 acquires a reference magnetic pattern indicating a result obtained by repeatedly measuring an indoor magnetic field by an indoor movement of a reference data collection apparatus including a magnetic sensor. In the reference magnetic pattern, a measurement position and each measured magnetic field are associated with each other.

The magnetic sensor measures, for example, a strength of a magnetic field in directions of three axes. The reference magnetic pattern indicates a temporal change of the strength of the measured magnetic field in each axis direction according to a movement of the reference data collection apparatus. The reference data collection apparatus is a communication apparatus having a communication function. The reference data collection apparatus is, for example, a user terminal that is carried by a user, and includes a smartphone, a mobile phone, a tablet terminal, a wearable terminal, an IoT terminal, a portable game machine, and a dedicated terminal. On the other hand, the reference data collection apparatus is not limited thereto.

The reference data collection apparatus may move according to walking of the user or a movement of a vehicle on which the user rides (for example, a bicycle, a car, a bus, a truck, a train). Further, in a case where the reference data collection apparatus is a self-traveling apparatus such as a robot, a drone, a carriage, or a car, the reference data collection apparatus itself may move.

The reference magnetic pattern is the same data as the target magnetic pattern illustrated in FIG. 3. The reference magnetic pattern indicates a result obtained by repeatedly measuring a strength of a magnetic field in each axis direction while the reference data collection apparatus is moving from an indoor mₛ position to an indoor mₑ position. In the reference magnetic pattern, a horizontal axis indicates a movement distance from the mₛ position when the mₛ position is set as an origin.

The training data generation unit 116 extracts, from the reference magnetic pattern, an interest magnetic pattern corresponding to predetermined frequency components by using a digital filter such as a bandpass filter. That is, the training data generation unit 116 extracts predetermined frequency components from each magnetic pattern by applying a bandpass filter to each magnetic pattern indicating a temporal change of the strength of the magnetic field in each axis direction. In the bandpass filter, for example, a stopband start end is 0.05 Hz, a passband start end is 0.1 Hz, a passband end is 0.8 Hz, and a stopband end is 1.0 Hz. The training data generation unit 116 generates machine learning training data required for generating the estimation model, based on the interest magnetic pattern.

The training data generation unit 116 cuts out, from the interest magnetic pattern, a learning pattern indicating a partial transition of a transition (a temporal change) of the measured magnetic field in each axis direction indicated by the interest magnetic pattern. That is, the interest magnetic pattern related to a partial movement path of a movement path from the mₛ position to the mₑ position is cut out as a learning pattern. The training data generation unit 116 generates training data assigned to the cut-out learning pattern by using, as a label, position information indicating an indoor position (an end point of the partial movement path) at which the magnetic field measured at a last timing in the transition (the partial transition) of the measured magnetic field indicated by the cut-out learning pattern is measured.

Note that the training data generation unit 116 can cut out a plurality of learning patterns having different lengths (different lengths in the partial movement path) from the interest magnetic pattern. Further, the training data generation unit 116 can divide an indoor area into a plurality of areas, and assign, as a label, identification information for identifying the areas to the learning patterns. The training data generation unit 116 can cut out, from the interest magnetic pattern, as learning patterns assigned to a first area using a label, a plurality of learning patterns in which the measurement positions of the magnetic field (end points of the partial movement path) measured at a last timing in the transition (the partial transition) of the measured magnetic field indicated by the learning pattern are different positions in the first area.

Note that, instead of the learning pattern represented by the magnetic pattern, data indicating a feature of the learning pattern may be used as learning data (training data). A specific example of processing by the training data generation unit 116 will be described in the following examples.

The estimation model generation unit 117 generates an estimation model for estimating a current indoor position by performing machine learning on the training data generated by the training data generation unit 116.

As described above, according to the indoor position estimation apparatus 100 of the present example embodiment, the same advantageous effects as those of the first example embodiment are realized.

Further, according to the indoor position estimation apparatus 100 of the present example embodiment, it is possible to generate a large amount of training data including various learning patterns from the reference magnetic data obtained by one movement. The magnetic sensor performs measurement, for example, in a period of several tens of milliseconds. Each sensing timing is considered as an end of the learning pattern for training, and thus various learning patterns can be extracted from the reference magnetic data obtained by one movement. Further, up-sampling may be performed on the acquired information. Thereby, the number of the learning patterns to be extracted can be further increased. By performing machine learning using a large amount of training data including various learning patterns, it is possible to improve position estimation accuracy of the position estimation target.

### Third Example Embodiment

The indoor position estimation apparatus 100 according to the present example embodiment includes units for performing position estimation with high accuracy without being influenced by an orientation of the magnetic sensor. Hereinafter, details will be described.

An example of the hardware configuration of the indoor position estimation apparatus 100 according to the present example embodiment is the same as those of the first and second example embodiments.

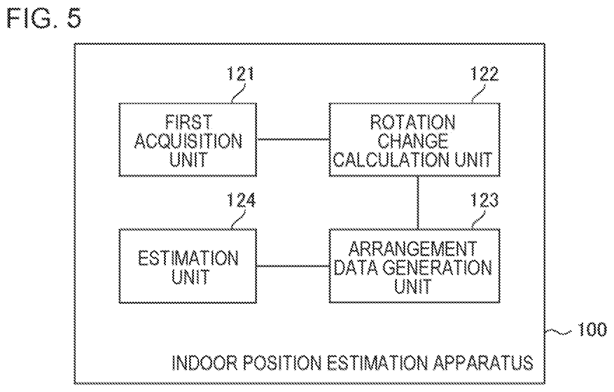

FIG. 5 illustrates an example of a functional block diagram of the indoor position estimation apparatus 100. As illustrated in FIG. 5, the indoor position estimation apparatus 100 includes a first acquisition unit 121, a rotation change calculation unit 122, an arrangement data generation unit 123, and an estimation unit 124.

The configuration of the first acquisition unit 121 is the same as that of the first acquisition unit 111 described in the first and second example embodiments. Note that, in the present example embodiment, an electronic compass is used as the magnetic sensor.

The rotation change calculation unit 122 calculates target magnetic patterns for each rotation amount, which indicate a simulation result obtained by rotating the target magnetic pattern around the vertical axis by a predetermined rotation amount (an angle equal to or larger than 0° and smaller than 360° in a case where an angle when the target magnetic pattern is measured is set to 0°), based on the target magnetic pattern acquired from the first acquisition unit 121. Rotating the target magnetic pattern around the vertical axis by a predetermined rotation amount corresponds to repeatedly measuring the strength of the magnetic field in each axis direction while the position estimation target is moving from the nₛ position to the nₑ position in a state where the magnetic sensor included in the position estimation target is rotated around the vertical axis by the predetermined rotation amount. The rotation change calculation unit 122 calculates target magnetic patterns for each rotation amount of a plurality of rotation amounts. The calculation method is a design matter.

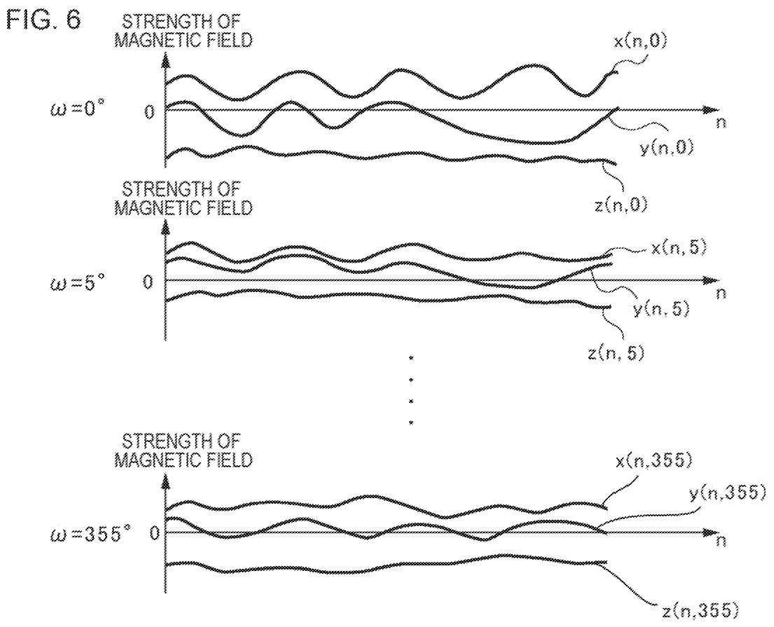

FIG. 6 schematically illustrates an example of the target magnetic patterns for each rotation amount. The target magnetic patterns for each rotation amount in each axis of the x-axis, the y-axis, and the z-axis are illustrated for each rotation amount ω. In FIG. 6, the target magnetic patterns for each rotation amount of every 5° are illustrated. On the other hand, a minimum unit of the rotation amount is not limited thereto. In the graph of FIG. 6, a vertical axis indicates a strength of the magnetic field, and a horizontal axis indicates a movement distance, that is, a movement distance from the nₛ position. The strength of the magnetic field on the vertical axis may be indicated in units of [A/m], or may be indicated by a value obtained by normalizing a value indicated in units of [A/m]. The movement distance can be calculated based on, for example, an elapsed time from when measurement is performed at the nₛ position and a general walking velocity. Note that the illustrated data is an image diagram and is not an actual simulation result.

Returning to FIG. 5, the arrangement data generation unit 123 generates target arrangement data in which the target magnetic patterns for each rotation amount of rotation amounts satisfying a first condition are first arranged and other target magnetic patterns for each rotation amount are arranged in order of rotation amount.

First, the arrangement data generation unit 123 determines an nₖ position satisfying a second condition on the movement path from the nₛ position to the nₑ position. For example, the arrangement data generation unit 123 determines, as the nₖ position, the nₛ position or the nₑ position. The arrangement data generation unit 123 determines, as the rotation amount satisfying the first condition, the rotation amount at which the strength of the magnetic field in a predetermined axis direction at the nₖ position is maximum or minimum.

The order of rotation amount may be ascending order (for example, 5, 10, 15, 20, . . . ). In this case, the target magnetic patterns for each rotation amount of rotation amounts satisfying the first condition are first arranged, and then the target magnetic patterns for each rotation amount of rotation amounts larger than the rotation amount satisfying the first condition are arranged in ascending order. Then, the target magnetic patterns for each rotation amount of rotation amounts smaller than the rotation amount satisfying the first condition are arranged in ascending order.

Further, the order of rotation amount may be descending order (for example, 355, 350, 345, 340, . . . ). In this case, the target magnetic patterns for each rotation amount of rotation amounts satisfying the first condition are first arranged, and then the target magnetic patterns for each rotation amount of rotation amounts smaller than the rotation amount satisfying the first condition are arranged in descending order. Then, the target magnetic patterns for each rotation amount of rotation amounts larger than the rotation amount satisfying the first condition are arranged in descending order.

The estimation unit 124 obtains an estimation result of the indoor position of the position estimation target by inputting data related to the target arrangement data generated by the arrangement data generation unit 123 into the estimation model obtained by machine learning. The data related to the target arrangement data may be the target arrangement data or data indicating a feature of the target arrangement data.

Next, an advantageous effect of the indoor position estimation apparatus 100 according to the present example embodiment will be described.

The indoor position estimation apparatus 100 according to the present example embodiment uses an electronic compass for positioning. Thereby, instantaneous magnetic information is also extracted as a two-dimensional magnetic pattern or a three-dimensional magnetic pattern. In a case where the electronic compass has a two-dimensional shape, the electronic compass needs to be provided horizontally to the ground. On the other hand, in a case where the electronic compass has a three-dimensional shape and the position estimation target includes a three-dimensional acceleration sensor, by calibration called zero calibration using gravitational acceleration, a three-dimensional magnetic pattern with a fixed vertical axis can be calculated.

Further, in a case where the position estimation target includes a three-dimensional acceleration sensor and a three-dimensional gyro sensor in addition to the electronic compass, once the vertical axis is fixed, a Kalman filter or the like can be used. Thus, even when an angle of the electronic compass is changed according to the movement of the position estimation target, it is possible to calibrate the vertical axis to a fixed output.

In the configuration of the indoor position estimation apparatus 100 according to the present example embodiment, even in a case where the target magnetic pattern is measured in a state where the magnetic sensor faces a first direction of a horizontal plane, and even in a case where the target magnetic pattern is measured in a state where the magnetic sensor faces a second direction of the horizontal plane, the target arrangement data indicating the same contents can be generated. Therefore, it is possible to perform position estimation with high accuracy without being influenced by an orientation of the magnetic sensor with respect to the horizontal plane.

As described above, according to the indoor position estimation apparatus 100 of the present example embodiment, it is possible to perform position estimation of the position estimation target with high accuracy without being influenced by an orientation of the magnetic sensor.

### Fourth Example Embodiment

The indoor position estimation apparatus 100 according to the present example embodiment is different from the indoor position estimation apparatus 100 according to the third example embodiment, in that units for generating an estimation model to be used in position estimation by the estimation unit 124 are further included in addition to the configuration described in the third example embodiment. Other configurations are the same as in the third example embodiment. Hereinafter, details will be described.

An example of the hardware configuration of the indoor position estimation apparatus 100 according to the present example embodiment is the same as those of the first to third example embodiments.

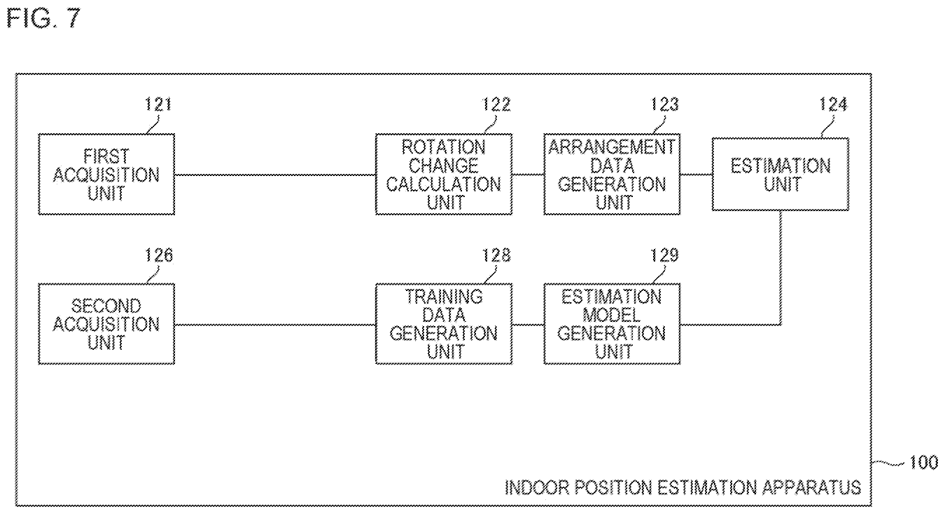

FIG. 7 illustrates an example of a functional block diagram of the indoor position estimation apparatus 100. As illustrated in FIG. 7, the indoor position estimation apparatus 100 includes a first acquisition unit 121, a rotation change calculation unit 122, an arrangement data generation unit 123, an estimation unit 124, a second acquisition unit 126, a training data generation unit 128, and an estimation model generation unit 129. The configurations of the first acquisition unit 121, the rotation change calculation unit 122, the arrangement data generation unit 123, and the estimation unit 124 are the same as those of the third example embodiment.

The second acquisition unit 126 acquires a reference magnetic pattern indicating a result obtained by repeatedly measuring an indoor magnetic field by an indoor movement of a reference data collection apparatus including a magnetic sensor. In the reference magnetic pattern, a measurement position and each measured magnetic field are associated with each other.

The magnetic sensor is an electronic compass, and measures, for example, a strength of a magnetic field in directions of three axes. The reference magnetic pattern indicates a temporal change of the strength of the measured magnetic field in each axis direction according to a movement of the reference data collection apparatus. The reference data collection apparatus is a communication apparatus having a communication function. The reference data collection apparatus is, for example, an apparatus that is carried by a user, and includes a smartphone, a mobile phone, a tablet terminal, a wearable terminal, an IoT terminal, a portable game machine, and a dedicated terminal. On the other hand, the reference data collection apparatus is not limited thereto. The reference data collection apparatus may move according to walking of the user or a movement of a vehicle on which the user rides (for example, a bicycle, a car, a bus, a truck, a train). Further, in a case where the reference data collection apparatus is a self-traveling apparatus such as a robot, a drone, a carriage, or a car, the reference data collection apparatus itself may move.

The reference magnetic pattern is the same data as the target magnetic pattern illustrated in FIG. 3. The reference magnetic pattern indicates a result obtained by repeatedly measuring a strength of a magnetic field in each axis direction while the reference data collection apparatus is moving from an indoor mₛ position to an indoor mₑ position. In the reference magnetic pattern, a horizontal axis indicates a movement distance from the mₛ position when the mₛ position is set as an origin.

The training data generation unit 128 generates machine learning training data required for generating the estimation model, based on the reference magnetic pattern.

First, the training data generation unit 128 calculates reference magnetic patterns for each rotation amount, which indicate a simulation result obtained by rotating the reference magnetic pattern around the vertical axis by a predetermined rotation amount (an angle equal to or larger than 0° and smaller than 360° in a case where an angle when the reference magnetic pattern is measured is set to 0°), based on the reference magnetic pattern acquired from the second acquisition unit 126. Rotating the reference magnetic pattern around the vertical axis by a predetermined rotation amount corresponds to repeatedly measuring the strength of the magnetic field in each axis direction while the reference data collection apparatus is moving from the mₛ position to the mₑ position in a state where the magnetic sensor included in the reference data collection apparatus is rotated around the vertical axis by the predetermined rotation amount. The training data generation unit 128 calculates reference magnetic patterns for each rotation amount of a plurality of rotation amounts. The processing by the training data generation unit 128 is the same as the processing of calculating a plurality of target magnetic patterns for each rotation amount based on the target magnetic pattern by the rotation change calculation unit 122.

Thereafter, the training data generation unit 128 extracts, from each of a plurality of reference magnetic patterns for each rotation amount, partial reference magnetic patterns for each rotation amount that correspond to data related to the partial movement path of the movement path from the mₛ position to the mₑ position. The training data generation unit 128 generates reference arrangement data in which the partial reference magnetic patterns for each rotation amount of rotation amounts satisfying a third condition are first arranged and other partial reference magnetic patterns for each rotation amount are arranged in order of rotation amount. The training data generation unit 128 can determine, as the rotation amount satisfying the third condition, the rotation amount at which the strength of the magnetic field in the predetermined axis direction on a start point or an end point of the partial movement path is maximum or minimum. The processing by the training data generation unit 128 is the same as the processing of arranging a plurality of target magnetic patterns for each rotation amount by the arrangement data generation unit 123.

The training data generation unit 128 generates training data by assigning, as a label, position information indicating an end point of the partial movement path to the generated reference arrangement data. Note that, instead of the reference arrangement data, data indicating a feature of the reference arrangement data may be used as learning data (training data).

Note that, the training data generation unit 128 can extract, from the reference magnetic patterns for each rotation amount, a plurality of partial reference magnetic patterns for each rotation amount that have different lengths in the partial movement path. Further, the training data generation unit 128 can divide an indoor area into a plurality of areas, and assign, as a label, identification information for identifying the areas to the learning patterns. The training data generation unit 128 can extract, from the reference magnetic patterns for each rotation amount, as the partial reference magnetic patterns (learning patterns) for each rotation amount that are assigned to the first area using a label, the plurality of learning patterns in which the end points of the movement path are different positions in the first area.

Here, a modification example of the processing of the training data generation unit 128 will be described. In the processing example described above, the training data generation unit 128 generates the reference arrangement data by generating the reference magnetic patterns for each rotation amount, extracting the plurality of partial reference magnetic patterns for each rotation amount, and arranging the extracted the reference magnetic patterns in a predetermined order. In the modification example, the training data generation unit 128 may generate the reference arrangement data by extracting, from the reference magnetic pattern, the partial reference magnetic pattern corresponding to data related to the partial movement path, generating the plurality of partial reference magnetic patterns for each rotation amount based on the partial reference magnetic pattern, and arranging the generated reference magnetic patterns for each rotation amount in a predetermined order.

The estimation model generation unit 129 generates an estimation model for estimating a current indoor position by performing machine learning on the training data generated by the training data generation unit 128.

As described above, according to the indoor position estimation apparatus 100 of the present example embodiment, the same advantageous effects as those of the third example embodiment are realized.

Further, according to the indoor position estimation apparatus 100 of the present example embodiment, it is possible to generate a large amount of training data including various learning patterns from the reference magnetic data obtained by one movement. The magnetic sensor performs measurement, for example, in a period of several tens of milliseconds. Each sensing timing is considered as an end of the learning pattern for training, and thus various learning patterns can be extracted from the reference magnetic data obtained by one movement. Further, up-sampling may be performed on the acquired information. Thereby, the number of the learning patterns to be extracted can be further increased. By performing machine learning using a large amount of training data including various learning patterns, it is possible to improve position estimation accuracy of the position estimation target.

### Fifth Example Embodiment

The indoor position estimation apparatus 100 according to the present example embodiment is different from the indoor position estimation apparatuses 100 according to the third and fourth example embodiments, in that predetermined processing is performed using only predetermined frequency components of the measured magnetic pattern. Other configurations are the same as in the third and fourth example embodiments. Hereinafter, details will be described.

An example of the hardware configuration of the indoor position estimation apparatus 100 according to the present example embodiment is the same as those of the first to fourth example embodiments.

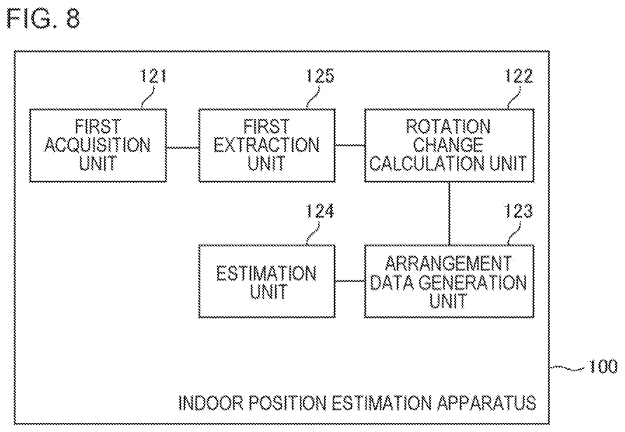

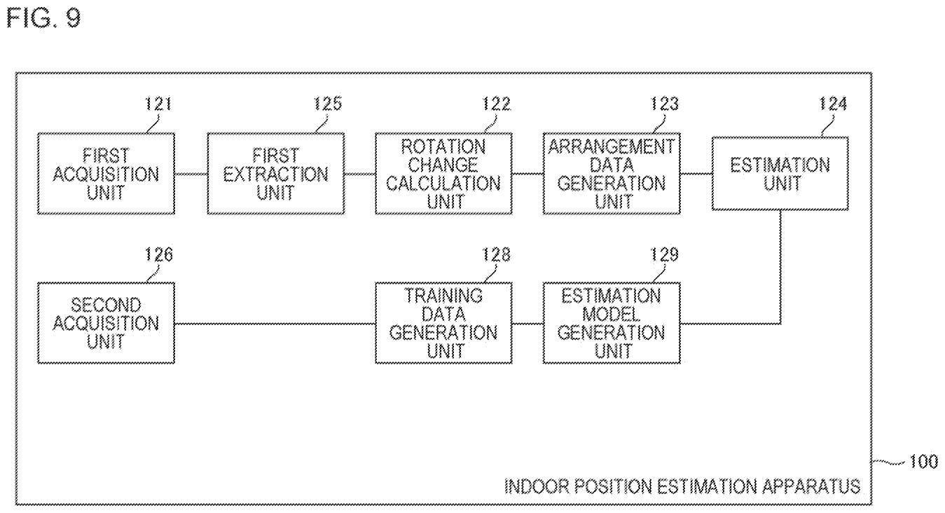

An example of a functional block diagram of the indoor position estimation apparatus 100 according to the present example embodiment is illustrated in FIGS. 8 and 9. In the example illustrated in FIG. 8, the indoor position estimation apparatus 100 includes a first acquisition unit 121, a rotation change calculation unit 122, an arrangement data generation unit 123, an estimation unit 124, and a first extraction unit 125.

In the example illustrated in FIG. 9, the indoor position estimation apparatus 100 includes a first acquisition unit 121, a rotation change calculation unit 122, an arrangement data generation unit 123, an estimation unit 124, a first extraction unit 125, a second acquisition unit 126, a training data generation unit 128, and an estimation model generation unit 129.

The configurations of the first acquisition unit 121, the arrangement data generation unit 123, the estimation unit 124, the second acquisition unit 126, and the estimation model generation unit 129 are the same as those in the third and fourth example embodiments.

The first extraction unit 125 extracts predetermined frequency components from the target magnetic pattern by using a digital filter such as a bandpass filter. That is, the first extraction unit 125 extracts predetermined frequency components from each magnetic pattern by applying a bandpass filter to each magnetic pattern indicating a temporal change of the strength of the magnetic field in each axis direction. In the bandpass filter, for example, a stopband start end is 0.05 Hz, a passband start end is 0.1 Hz, a passband end is 0.8 Hz, and a stopband end is 1.0 Hz.

The rotation change calculation unit 122 calculates target magnetic patterns for each rotation amount based on the predetermined frequency components of the target magnetic pattern. Other configurations other than the rotation change calculation unit 122 are the same as in the third and fourth example embodiments.

The training data generation unit 128 extracts predetermined frequency components from the reference magnetic pattern by using a digital filter such as a bandpass filter. That is, the training data generation unit 128 extracts predetermined frequency components from each magnetic pattern by applying a bandpass filter to each magnetic pattern indicating a temporal change of the strength of the magnetic field in each axis direction. In the bandpass filter, for example, a stopband start end is 0.05 Hz, a passband start end is 0.1 Hz, a passband end is 0.8 Hz, and a stopband end is 1.0 Hz. The training data generation unit 128 calculates reference magnetic patterns for each rotation amount based on the predetermined frequency components of the reference magnetic pattern. Other configurations other than the training data generation unit 128 are the same as in the third and fourth example embodiments.

As described above, according to the indoor position estimation apparatus 100 of the present example embodiment, the same advantageous effects as those of the third and fourth example embodiments are realized. Further, according to the indoor position estimation apparatus 100 of the present example embodiment, which performs processing using only the predetermined frequency components of the magnetic pattern, the same advantageous effect as those of the first and second example embodiments are realized.

### Example 1

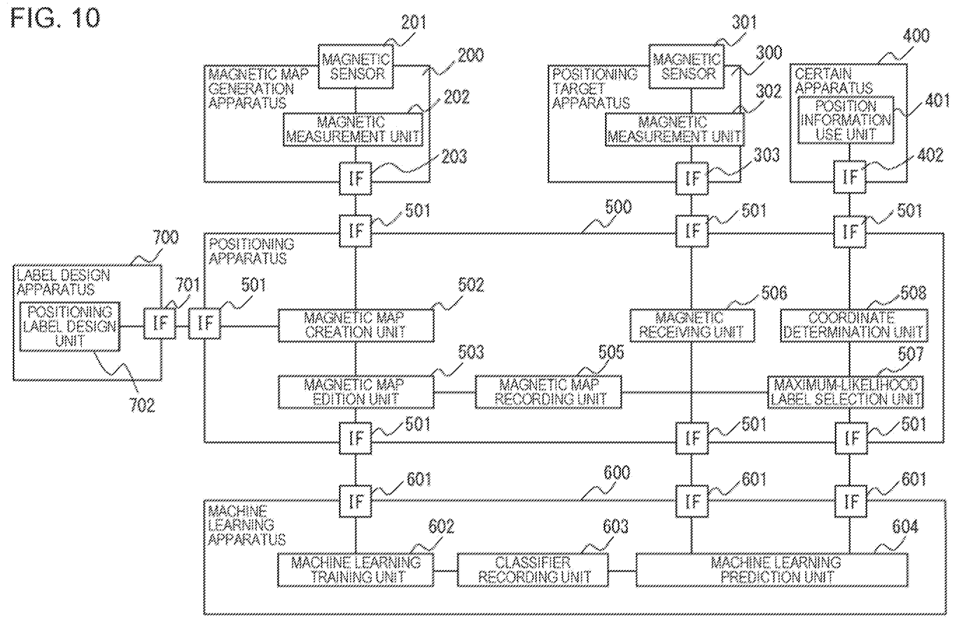

An example for embodying the example embodiment will be described. FIG. 10 is a diagram illustrating a configuration of a positioning magnetic map creation system according to an example 1. With reference to FIG. 10, a configuration in which a magnetic map generation apparatus 200, a positioning target apparatus 300, a certain apparatus 400, a positioning apparatus 500, a machine learning apparatus 600, and a label design apparatus 700 are connected is illustrated. The indoor position estimation apparatus 100 described in the first to fifth example embodiments is realized by at least a part of the magnetic map generation apparatus 200, the positioning apparatus 500, the machine learning apparatus 600, and the label design apparatus 700. The position estimation target described in the first to fifth example embodiments is realized by the positioning target apparatus 300. The magnetic sensor included in the position estimation target described in the first to fifth example embodiments is realized by a magnetic sensor 301. A magnetic measurement unit 302 acquires the target magnetic pattern described in the first to fifth example embodiments.

In FIG. 10, IF 203, 303, 402, 501, 601, or 701 represents a wired communication IF, a wireless communication IF, a storage IF, or a user IF, which can perform data exchange between the apparatuses, and various IFs may be adopted according to a physical connection configuration between the apparatuses and a standard supported by each apparatus. The target magnetic pattern, which is acquired by the position estimation target described in the first to fifth example embodiments, is transmitted by the IF 303 to the indoor position estimation apparatus 100 described in the first to fifth example embodiments.

The magnetic map generation apparatus 200 includes a magnetic sensor 201 and a magnetic measurement unit 202. The magnetic measurement unit 202 creates a “magnetic pattern in which magnetic fields measured by the magnetic sensor are arranged”, which is paired with a measurement path indicating a movement path at the time of measurement. The magnetic measurement unit 202 transmits the created measurement path and the created magnetic pattern (reference magnetic pattern) to the positioning apparatus 500 such that the created measurement path and the created magnetic pattern can be handled by the positioning apparatus 500. Instead of transmission of the measurement path and the magnetic pattern by the magnetic measurement unit 202, the magnetic measurement unit 202 may move or copy the measurement path and the magnetic pattern to a location (a physical storage or a network storage) which is accessible from the positioning apparatus 500.

The positioning apparatus 500 includes a magnetic map creation unit 502, a magnetic map edition unit 503, a magnetic map recording unit 505, a magnetic pattern receiving unit 506, a maximum-likelihood label selection unit 507, and a coordinate determination unit 508.

The magnetic map creation unit 502 reads the “magnetic pattern measured along the measurement path” created by the magnetic map generation apparatus 200. The magnetic map creation unit 502 creates a map (associated array) by applying a bandpass filter to a magnetic pattern, generating a magnetic pattern in which the DC component and the frequency components equal to or higher than a vibration frequency caused by the movement are removed from the magnetic pattern, and assigning a unique identifier to the generated magnetic pattern. In the map, the measurement path identifier is included as a key, and the measurement path coordinate and the magnetic pattern after filter processing are included as values. The magnetic map creation unit 502 outputs, as a magnetic map, the created map to the magnetic map edition unit 503.

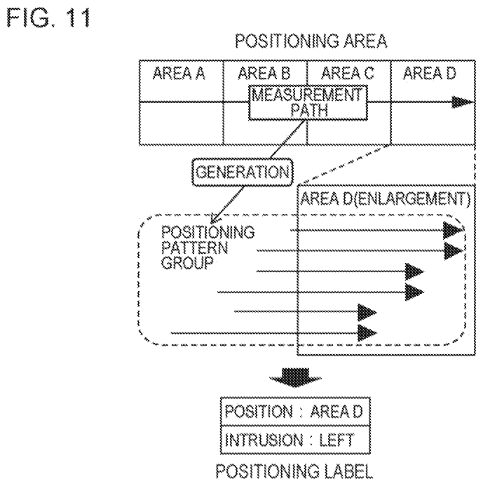

The magnetic map edition unit 503 creates a learning magnetic map by converting the magnetic map created by the magnetic map creation unit 502 into a positioning object. The positioning object includes a positioning label and a positioning pattern. The positioning label includes information in which a positioning area indicated by a polygon and another positioning area adjacent to each side of the positioning area are paired (for example, in FIG. 11, a positioning area paired with an area D is an area C, and positioning areas paired with an area C are an area B and an area D) and information indicating an intrusion from a side of a positioning area (for example, in FIG. 11, for a positioning area C, information indicating an intrusion from a left side or an intrusion from a right side is considered). The positioning pattern includes a magnetic pattern of which the end includes magnetic information on a certain point in a positioning area, and a length of the magnetic pattern. The “magnetic pattern of which the end includes magnetic information on a certain point in a positioning area” is a partial pattern cut out from the magnetic pattern after filter processing.

In a case of the example illustrated in FIG. 11, the measurement path is a path from a left end of the area A to a right end of the area D, and one magnetic pattern is generated in a movement along the measurement path. After performing filter processing on one magnetic pattern, a plurality of positioning patterns are extracted from the magnetic pattern after the filter processing. In the example illustrated in FIG. 11, six positioning patterns are illustrated. In the six positioning patterns, at least one of a start position and an end position is different from each other. Thus, different magnetic patterns are illustrated. Further, in all of the six positioning patterns illustrated in FIG. 6, the ends are in the same area D. In the six positioning patterns, there are positioning patterns in which the end positions are different in the area D. In this way, a plurality of positioning patterns indicating the same positioning label are generated.

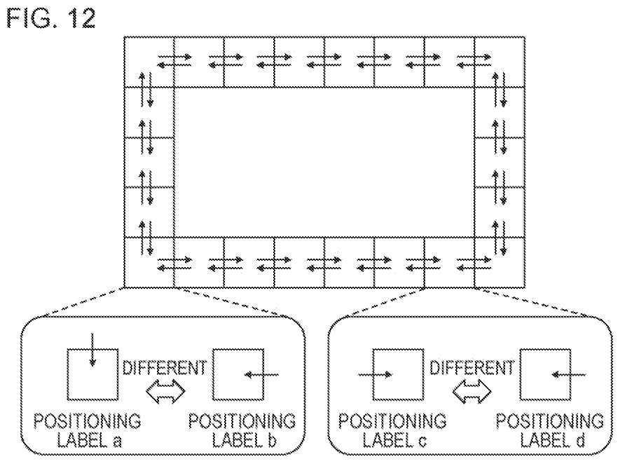

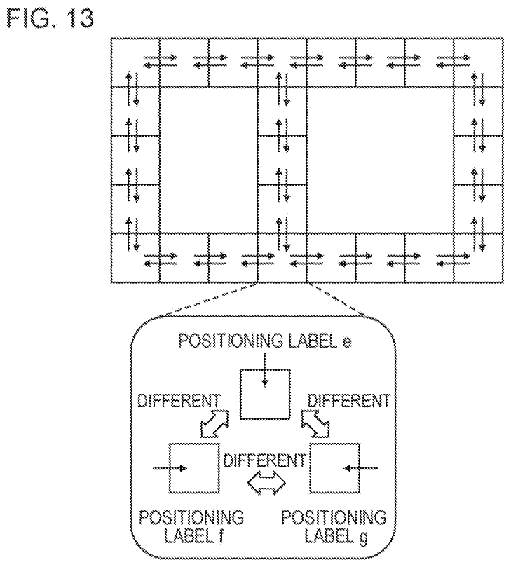

FIGS. 12 and 13 are diagrams for explaining a relationship between the positioning label and the positioning pattern.

FIG. 12 illustrates a relationship between the positioning label and the positioning pattern in a square passage. In all positioning areas, there are two sides that allow an intrusion, and two directions are generally reversed. Only in the area corresponding to a corner, two directions are in an orthogonal relationship. A direction near an end of a vector of the magnetic pattern before turning the corner and a direction near an end of a vector of the magnetic pattern after turning the corner are orthogonal. On the other hand, sides that intrude into the positioning area are the same. Since there are two sides that allow an intrusion, there are two positioning labels in the same positioning area.

FIG. 13 illustrates a relationship between the positioning label and the positioning pattern in a passage at which two squares are connected. In the positioning area corresponding to an intersection of a T-shaped junction, there are three sides that allow an intrusion. Thus, even in the same positioning area, there are three positioning labels.

The magnetic map edition unit 503 stores the converted magnetic map in the magnetic map recording unit 505, and outputs, as a learning magnetic map, the converted magnetic map to the machine learning apparatus 600.

Some or all of the functions of the second acquisition unit 114, the second acquisition unit 126, the training data generation unit 116, the training data generation unit 128, and the like correspond to the functions of the magnetic map creation unit 502 and the magnetic map edition unit 503.

The magnetic pattern receiving unit 506 receives a positioning magnetic pattern (target magnetic pattern) from the positioning target apparatus 300. First, the magnetic pattern receiving unit 506 converts the positioning magnetic pattern into information only on a specific frequency band by applying a digital filter such as a bandpass filter similar to the bandpass filter of the magnetic map creation unit 502 to the positioning magnetic pattern. Next, the magnetic pattern receiving unit 506 converts the positioning magnetic pattern into a positioning pattern including a magnetic pattern and a length of the magnetic pattern, and transmits the positioning pattern to the machine learning apparatus 600.

The maximum-likelihood label selection unit 507 receives, as a response to the positioning pattern, likelihood of each of a plurality of positioning labels from the machine learning apparatus 600. Next, the maximum-likelihood label selection unit 507 outputs, as an estimated positioning label, the positioning label having highest likelihood. The coordinate determination unit 508 outputs, as an estimated coordinate, a coordinate of the positioning area with the estimated positioning label received from the maximum-likelihood label selection unit 507. The output estimated coordinate is used, for example, by a position information use unit 401 included in the certain apparatus 400. Examples of the position information use unit 401 include a map application program, a navigation application program, and the like installed in the certain apparatus 400.

Some or all of the functions of the first acquisition unit 111, the first acquisition unit 121, the first extraction unit 112, the first extraction unit 125, the estimation unit 113, the estimation unit 124, and the like correspond to the functions of the maximum-likelihood label selection unit 507 and the coordinate determination unit 508.

The machine learning apparatus 600 includes a machine learning training unit 602, a classifier recording unit 603, and a machine learning prediction unit 604.

The machine learning training unit 602 generates a learning model by performing machine learning training based on each positioning object of the learning magnetic map created by the magnetic map edition unit 503. The positioning label corresponds to a training label, and the positioning pattern corresponds to the training data. The machine learning training unit 602 stores, as a classifier, the generated learning model in the classifier recording unit 603.

When receiving the positioning pattern of the positioning target from the magnetic pattern receiving unit 506 of the positioning apparatus 500, the machine learning prediction unit 604 obtains likelihood of each positioning label by inputting the positioning pattern of the positioning target to the classifier stored in the classifier recording unit 603. The machine learning prediction unit 604 transmits the likelihood of each positioning label obtained by using the classifier to the positioning apparatus 500.

Some or all of the functions of the estimation model generation unit 117, the estimation model generation unit 129, and the like correspond to the functions of the machine learning training unit 602.

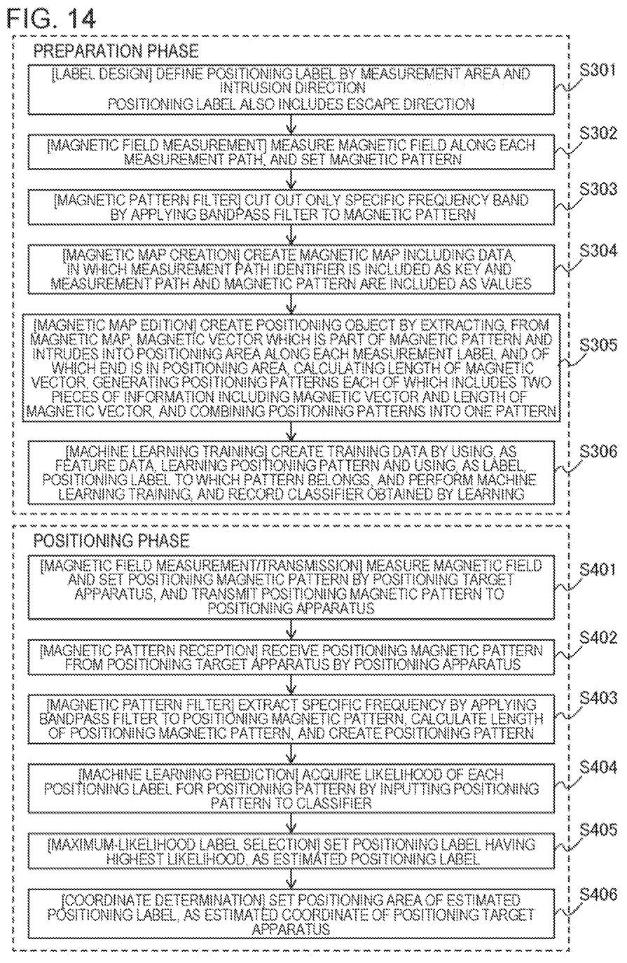

Subsequently, with reference to a flowchart of FIG. 14, a flow of an overall operation of the positioning magnetic map creation system according to the example 1 will be described.

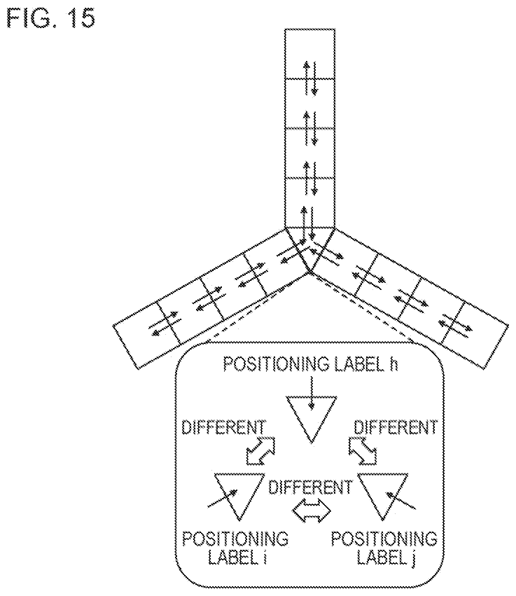

As illustrated in FIG. 14, in a preparation phase, first, a label design unit 702 of the label design apparatus 700 performs label design (step S301). Specifically, as illustrated in FIGS. 12 and 13, a polygonal positioning area and an intrusion path to the positioning area are set for a range of the positioning target, and a positioning label is generated for each combination. The positioning label also holds an escape path from the positioning area. The positioning area does not need to have the same polygonal shape. For example, an intersection of a three-way junction may be indicated by a triangle, and an intersection of a five-way junction may be indicated by a pentagon. FIG. 15 illustrates a positioning label at an intersection of a three-way junction.

Next, the magnetic map generation apparatus 200 performs magnetic measurement along each measurement path and creation of a magnetic pattern (step S302).

Next, the positioning apparatus 500 extracts only a specific frequency band by applying a digital filter such as a bandpass filter to the magnetic pattern created in step S302 (step S303). Next, the positioning apparatus 500 creates a magnetic map including data, in which the measurement path identifier is included as a key and the measurement path and the magnetic pattern are included as values (step S304).

Next, the positioning apparatus 500 creates a learning magnetic map by extracting a plurality of positioning objects from the magnetic map (step S305). Specifically, the positioning apparatus 500 creates a positioning object by extracting, from the magnetic map, a magnetic vector which is a part of the magnetic pattern and intrudes into a positioning area along each measurement label and of which the end is in the positioning area, calculating a length of the magnetic vector, generating positioning patterns each of which includes two pieces of information including the magnetic vector and the length of the magnetic vector, and combining the positioning patterns into one pattern.

Next, the machine learning apparatus 600 performs machine learning training using, as training data, the positioning pattern of the learning magnetic map and using, as a training label, the positioning label of the learning magnetic map, and records a classifier obtained by learning (step S306).

In a positioning phase, first, the positioning target apparatus 300 measures a magnetic field, and generates a positioning magnetic pattern based on the measured magnetic field. The positioning target apparatus 300 transmits the positioning magnetic pattern to the positioning apparatus 500 (step S401).

Next, when receiving the positioning magnetic pattern from the positioning target apparatus 300 (step S402), the positioning apparatus 500 extracts a specific frequency by applying a bandpass filter to the positioning magnetic pattern, calculates a length of the positioning magnetic pattern, and creates a positioning pattern (step S403). The positioning apparatus 500 transmits the created positioning pattern to the machine learning apparatus 600.

Next, the machine learning apparatus 600 acquires likelihood of each positioning label for the positioning pattern by inputting the received positioning pattern to the classifier, and transmits the acquired likelihood to the positioning apparatus 500 (step S404).

Next, the positioning apparatus 500 sets the positioning label having the highest likelihood, as the estimated positioning label (step S405). Finally, the positioning apparatus 500 sets a positioning area of the estimated positioning label, as an estimated coordinate of the positioning target apparatus (step S406).

Effects of the example 1 are as follows.

According to the example 1, only a magnetic influence obtained from a hard magnetic material can be extracted, and machine learning training based on the magnetic influence and a position of the hard magnetic material can be performed. Thus, the accurate position can be calculated. The reason is that a configuration for creating a classifier by removing geomagnetic information and magnetic information by filtering is adopted. The geomagnetic information has a largest influence on a positioning magnetic pattern since machine learning itself has a characteristic in that flexible determination is performed. On the other hand, the geomagnetic information is almost useless for position determination. Further, the magnetic information corresponds to largest external factor noise caused by movement.

A step of removing the geomagnetic information also contributes to a problem related to the offset deviation of the magnetic sensor. Similar to the geomagnetic information, the offset deviation is also output as a DC component. Thus, it is not necessary to perform calibration of the magnetic sensor in either of a preparation phase or a positioning phase.

The filtering step also contributes to reduction of development man-hours. The filtering step is simple processing of maintaining only a specific frequency band, and can be completed in a shorter time than in a step of individually determining and removing noise or a step of adding noise.

Further, the example 1 can solve a problem in that learning is performed based on innumerable magnetic patterns that intrude into the positioning areas, a problem in that there is a state where similar magnetic patterns cannot be found because the positioning magnetic patterns straddle the positioning areas, and a problem in that the likelihood is lowered.

Further, the example 1 can be released from a problem in that the length of the positioning magnetic pattern and the range of the positioning areas need to be matched. Thereby, even in a case where the length of the positioning area is short, the positioning magnetic pattern longer than the positioning area can be used for positioning. Therefore, positioning accuracy is improved.

### Example 2

An example 2 will be described with reference to FIG. 10. The example 2 is different from the example 1 in that the magnetic sensor is limited to an electronic compass, and in that the processing of the magnetic map edition unit 503 (S305 in FIG. 14) and the processing of the magnetic pattern receiving unit 506 (S403 in FIG. 14) are different.

As in the example 1, the magnetic map edition unit 503 creates a learning magnetic map by converting the magnetic map created by the magnetic map creation unit 502 into a positioning object. The magnetic map edition unit 503 creates a four-dimensional learning magnetic map by rotating the positioning pattern of the positioning object included in the learning magnetic map around the vertical axis and performing normalization such that the same magnetic information change vector is obtained even in a case where positioning is performed in a state where the vertical axis is rotated.

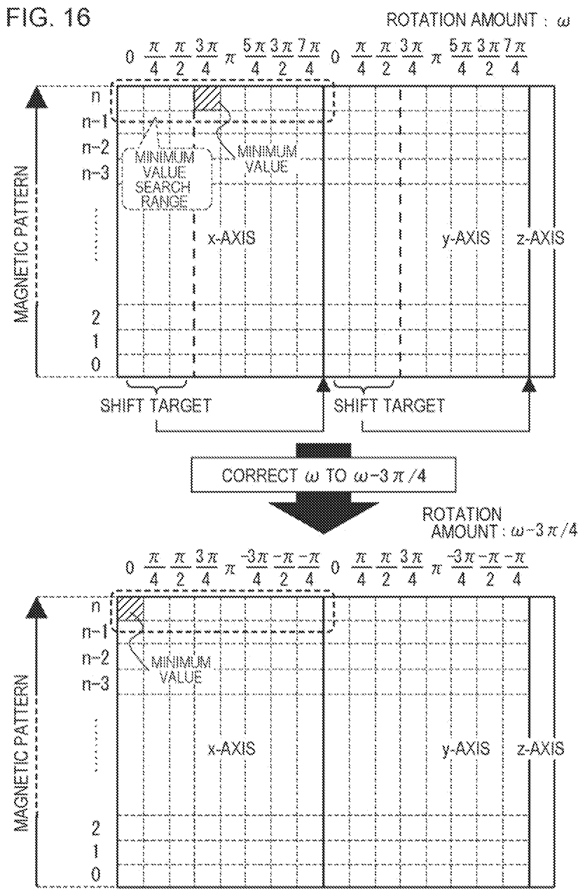

The magnetic pattern is expressed by a vector having a length n in three dimensions, and thus the vector is expressed as [x(n), y(n), z(n)]. The magnetic pattern included in the positioning pattern is rotated around the vertical axis, and a rotation amount ω and a change in the magnetic information on the x-axis and the y-axis of the horizontal plane are recorded. By this work, the vector is expressed by [x(n, ω), y(n, ω), z(n, ω)]. In a case where an end of the vector is p, assuming that ω when x(p, ω) is minimized is r and the order of the vector is changed by ω-r, the vector is expressed by [x(n, y(n, z(n, ω-r)]. FIG. 16 is a diagram illustrating a concept of the processing.

The magnetic pattern receiving unit 506 performs, on the positioning pattern, the same processing as the processing of the magnetic map edition unit 503.

In the example 2, in addition to the same effects as those in the example 1, the following effects are realized.

In the example 2, the positioning apparatus generates a magnetic pattern in which the influence of rotation around the vertical axis is negligible and uses the magnetic pattern for machine learning training. Thus, it is possible to perform position measurement without depending on rotation around the vertical axis.

Further, rotation other than the rotation around the vertical axis is calibrated by a certain unit such as a unit using an acceleration sensor, a gyro sensor, and a correction filter such as a Kalman filter. Thereby, it is possible to perform position measurement without depending on a way of holding the electronic compass.

Note that a system configuration may also be adopted in which any two or more apparatuses among the magnetic map generation apparatus 200, the positioning target apparatus 300, the positioning apparatus 500, the machine learning apparatus 600, and the label generation apparatus 700 illustrated in FIG. 10 are integrated into a single apparatus. For example, the magnetic map generation apparatus 200 and the positioning target apparatus 300 may be configured as the same apparatus.

Further, two or more processing units (functional units) illustrated in FIG. 10 may be integrated or further subdivided. For example, a system configuration in which the magnetic pattern receiving unit 506, the maximum-likelihood label selection unit 507, and the coordinate determination unit 508 are integrated into one processing unit may be adopted.

Further, a system configuration in which a part of two or more processing units illustrated in FIG. 10 is provided in another apparatus may also be adopted. For example, the maximum-likelihood label selection unit 507 and the coordinate determination unit 508 may be provided in the positioning target apparatus 300. Further, a configuration in which the positioning target apparatus 300 directly accesses the machine learning prediction unit 604 of the machine learning apparatus 600 and acquires likelihood of each positioning magnetic path may be adopted.

Further, in the magnetic map creation unit 502 and the magnetic pattern receiving unit 506, instead of applying a bandpass filter, a configuration in which a band stop filter is applied and the magnetic pattern output from the band stop filter is removed from the original magnetic pattern may be adopted. Further, a combination of a plurality of low-pass filters and high-pass filters may also be adopted.

Further, in the magnetic map edition unit 503, instead of using, as the positioning pattern, the value of the magnetic pattern as it is, a configuration in which normalization for relatively changing the value is performed such that the value falls within a fixed range may be adopted. Both of a configuration in which normalization is performed based on values of all measurement paths and a configuration in which normalization is performed using only a value in the positioning pattern may be adopted.

Further, in a case where the magnetic map edition unit 503 performs normalization on the positioning pattern using only a value in the positioning pattern, a configuration in which, when normalization is performed based on a width of the value, a multiplication factor according to the width of the value is applied may be adopted. As a method for calculating the multiplication factor, a linear function, a segment linear function, or a non-linear function may be adopted.

Further, in a case where the example 2 is executed by the magnetic map edition unit 503, a configuration in which rotation is performed even when a value of z(n) does not change, each axis of the x-axis, the y-axis, and the z-axis is normalized to a value of 0 to 255, and the normalized value is converted into an image with RGB may also be adopted.

Further, in a case where the example 2 is executed using an RGB image by the magnetic map edition unit 503, a configuration in which an RGB color space is converted into another color space such as HSV and machine learning is performed may be adopted.

Further, in a case where the example 2 is executed using an RGB image by the magnetic map edition unit 503, a configuration in which a calculation amount of machine learning is reduced by reducing a size of the image may be adopted. Similarly, a configuration in which a calculation amount is reduced by reducing a size of the image in another color space may be adopted.

In the present specification, a user terminal (user equipment, UE) (or including a mobile station, a mobile terminal, a mobile device, a wireless device, or the like) is an entity connected to a network through a wireless interface.

The present specification is not limited to a dedicated communication apparatus, and may be applied to any equipment having the following communication functions.

The terms “user terminal (user equipment, UE) (as a word used in 3GPP)”, “mobile station”, “mobile terminal”, “mobile device”, and “wireless device” are generally intended to be synonymous with each other, and may be a stand-alone mobile station such as a terminal, a mobile phone, a smartphone, a tablet, a cellular IoT terminal, an IoT device, or the like. It is understood that the terms “mobile station”, “mobile terminal”, and “mobile device” also include apparatuses provided for a long period of time.

Further, UE may be, for example, an item of production facilities/manufacturing facilities and/or energy-related machines (as an example, a boiler, an engine, a turbine, a solar panel, a wind power generator, a hydroelectric generator, a thermal power generator, a nuclear power generator, a storage battery, a nuclear system, a nuclear-related equipment, a heavy electrical equipment, a pump such as a vacuum pump, a compressor, a fan, a blower, a hydraulic equipment, a pneumatic equipment, a metal processing machine, a manipulator, a robot, a robot application system, a tool, a die, a roll, a transport apparatus, a lifting apparatus, a cargo handling apparatus, a textile machine, a sewing machine, a printing machine, a printing-related machine, a paper-making machine, a chemical machine, a mining machine, a mining-related machine, a construction machine, a construction-related machine, an agricultural machine and/or equipment, a forestry machine and/or equipment, a fishery machine and/or equipment, a safety and/or environmental protection equipment, a tractor, a bearing, a precision bearing, a chain, a gear, a power transmission apparatus, a lubricator, a valve, a pipe connector, and/or an application system for any equipment or machine mentioned above).

Further, UE may be, for example, an item of a transportation apparatus (as an example, a vehicle, an automobile, a motorcycle, a bicycle, a train, a bus, a handcart, a rickshaw, a ship (ship and other watercraft), an airplane, a rocket, an artificial satellite, a drone, a balloon, or the like).

Further, UE may be, for example, an item of an information communication apparatus (as an example, a computer and a computer-related apparatus, a communication apparatus and a communication-related apparatus, an electronic component, or the like).

Further, UE may be, for example, a refrigerator, a refrigerator application product and apparatus, a commercial and service equipment, a vending machine, an automatic service machine, an office machine and apparatus, or a consumer electrical and electronic machine (as an example, an audio equipment, a speaker, a radio, a video equipment, a television, a microwave oven, a rice cooker, a coffee maker, a dishwasher, a washing machine, a dryer, an electric fan, a ventilator and ventilator-related product, a vacuum cleaner, or the like).

Further, UE may be, for example, an electronic application system or an electronic application apparatus (as an example, an X-ray apparatus, a particle accelerator, a radioactive-material application apparatus, a sound wave application apparatus, an electromagnetic application apparatus, a power application apparatus, or the like).

Further, UE may be, for example, a light bulb, a lighting equipment, an electric meter, an analysis equipment, a testing machine and a measurement machine (as an example, a smoke detector, an alarm sensor, a motion sensor, a wireless tag, or the like), a timepiece (a watch or a clock), a physics and chemistry machine, an optical machine, a medical equipment and/or a medical system, a weapon, a cutting tool, or a hand tool.

Further, UE may be, for example, a personal digital assistant or apparatus having a wireless communication function (as an example, an electronic apparatus (for example, a personal computer, an electronic measuring instrument, or the like) configured to attach or insert a wireless card, a wireless module, or the like).

Further, UE may be, for example, an apparatus or a part of the apparatus that provides the following application programs, services, and solutions in “Internet of Things (IoT)” using wired or wireless communication techniques.

In IoT devices (or things), appropriate electronic devices, software, sensors, network connections, and the like are provided so as to allow the devices to collect and exchange data with each other and with other communication devices.

Further, the IoT device may be a device that automatically operates according to a software instruction stored in an internal memory.

Further, the IoT device may operate without requiring monitoring or a response by a person.

Further, the IoT device may be a device provided over a long period of time, and/or the IoT device may be in an inactive state for a long time.

Further, the IoT device may be provided as a part of a stationary apparatus. The IoT device may be embedded in a non-stationary apparatus (such as a vehicle), or may be attached to an animal or a person to be monitored/tracked.

It is understood that an IoT technique can be implemented in any communication device which can be connected to a communication network for transmitting and receiving data regardless of a control input from a person or a software instruction stored in a memory.

It is understood that the IoT device is referred to as a machine type communication (MTC) device or a machine-to-machine (M2M) communication device.

Further, it is understood that UE can support one or more IoT or MTC application programs.

Examples of MTC application programs are listed in a table below (source: 3GPP TS22.368 V13.2.0 (2017-01-13) Annex B, the contents of which are incorporated herein by reference). This list is not exhaustive. As an example, the list shows MTC application programs.

TABLE 1

| Service Range | MTC Application Program |
|---|---|
| Security | Monitoring system |
| | Landline backup |
| | Physical access controlling |
| | (for example, access to building) |
| | Car/driver security |
| Tracking & Tracing | Fleet management |
| | Order management |
| | Telematics insurance: PAYD |
| | (Pay as you drive) |
| | Asset management |
| | Navigation |
| | Traffic information |
| | Road tolling |
| | Road traffic optimisation/steering |
| Payment | Point of sales, POS |
| | Vending machines |
| | Gaming machines |
| Health | Monitoring vital signs |
| | Supporting the aged or handicapped |
| | Web Access Telemedicine points |
| | Remote diagnostics |
| Remote | Sensor |
| Maintenance/Control | Lighting |
| | Pumps |
| | Valves |
| | Elevator control |
| | Vending machine control |
| | Vehicle diagnostics |
| Metering | Power |
| | Gas |
| | Water |
| | Heating |
| | Grid control |
| | Industrial metering |
| Consumer | Devices Digital photo frame |
| | Digital camera |
| | Electronic book |

Examples of the application program, the service, and the solution may include a mobile virtual network operator (MVNO) service/system, a disaster prevention wireless service/system, a private wireless telephone (private branch exchange (PBX)) service/system, a PHS/digital cordless telephone service/system, a point of sale (POS) system, an advertising service/system, a multimedia broadcast and multicast service (MBMS) service/system, a V2X (vehicle to everything: vehicle-to-vehicle communication and road-to-vehicle/pedestrian-to-vehicle communication) service/system, an in-train mobile wireless service/system, a position-information-related service/system, a disaster/emergency wireless communication service/system, an Internet of things (IoT) service/system, a community service/system, a video distribution service/system, a Femto-cell application service/system, a voice over LTE (VoLTE) service/system, a wireless TAG service/system, a billing service/system, a radio on-demand service/system, a roaming service/system, a user behavior monitoring service/system, a communication carrier/communication NW selection service/system, a function restriction service/system, a proof of concept (PoC) service/system, a personal information management service/system for terminals, a display/video service/system for terminals, a non-communication service/system for terminals, and an ad hoc NW/delay tolerant networking (DTN) service/system.

Note that a UE category described above is merely an application example of the technical ideas and the example embodiments described in the present specification. The present disclosure is not limited to the examples, and it is needless to say that various changes may be made by those skilled in the art.

Hereinafter, an example of a reference embodiment will be described.

1. An indoor position estimation apparatus including:

a first acquisition unit that acquires a target magnetic pattern indicating a result obtained by repeatedly measuring an indoor magnetic field by a position estimation target including a magnetic sensor; a first extraction unit that extracts predetermined frequency components from the target magnetic pattern; and an estimation unit that obtains an estimation result of an indoor position of the position estimation target by inputting data on the extracted frequency components into an estimation model obtained by machine learning.

2. The indoor position estimation apparatus described in 1, further including: a second acquisition unit that acquires a reference magnetic pattern indicating a result obtained by repeatedly measuring a magnetic field by a reference data collection apparatus including a magnetic sensor while the reference data collection apparatus is moving in an indoor area; and a training data generation unit that extracts, from the reference magnetic pattern, an interest magnetic pattern corresponding to the predetermined frequency components and generates machine learning training data for generating the estimation model based on the interest magnetic pattern, in which, in the reference magnetic pattern, a measurement position is associated with each measured magnetic field.

3. The indoor position estimation apparatus described in 2, in which, the training data generation unit cuts out, from the interest magnetic pattern, a learning pattern indicating a partial transition of a transition of the measured magnetic field indicated by the interest magnetic pattern, and generates the training data assigned to data indicating the learning pattern or a feature of the learning pattern by using, as a label, position information indicating an indoor position at which the magnetic field is measured at a last timing in the partial transition.

4. The indoor position estimation apparatus described in 3, in which the training data generation unit cuts out, from the interest magnetic pattern, a plurality of the learning patterns having different lengths.

5. The indoor position estimation apparatus described in any one of 2 to 4, in which the training data generation unit divides an indoor area into a plurality of areas, assigns, as the label, identification information for identifying the areas to the data indicating the learning pattern or the feature of the learning pattern, and cuts out, from the interest magnetic pattern, the plurality of learning patterns in which measurement positions of the magnetic field measured at a last timing in the partial transition are different positions in a first area of the areas.

6. The indoor position estimation apparatus described in any one of 2 to 5, further including: an estimation model generation unit that generates the estimation model based on the training data.

7. An indoor position estimation method executed by a computer, the method including: a first acquisition step of acquiring a target magnetic pattern indicating a result obtained by repeatedly measuring an indoor magnetic field by a position estimation target including a magnetic sensor; a first extraction step of extracting predetermined frequency components from the target magnetic pattern; and an estimation step of obtaining an estimation result of an indoor position of the position estimation target by inputting data on the extracted frequency components into an estimation model obtained by machine learning.

8. A program causing a computer to function as: a first acquisition unit that acquires a target magnetic pattern indicating a result obtained by repeatedly measuring an indoor magnetic field by a position estimation target including a magnetic sensor; a first extraction unit that extracts predetermined frequency components from the target magnetic pattern; and an estimation unit that obtains an estimation result of an indoor position of the position estimation target by inputting data on the extracted frequency components into an estimation model obtained by machine learning.

9. A user terminal including: a magnetic sensor that measures an indoor magnetic field; an acquisition unit that acquires a target magnetic pattern indicating a result measured by the magnetic sensor; and a communication unit that transmits the target magnetic pattern to an indoor position estimation apparatus that estimates a position of the user terminal in an indoor area based on predetermined frequency components included in the target magnetic pattern.

10. An indoor position estimation apparatus including: a first acquisition unit that acquires a target magnetic pattern indicating a result obtained by repeatedly measuring an indoor magnetic field by a position estimation target including a magnetic sensor; a first extraction unit that extracts predetermined frequency components from the target magnetic pattern; and an estimation unit that obtains an estimation result of an indoor position of the position estimation target based on the extracted frequency components.

This application is based upon and claims the benefit of priority from Japanese Patent Application No. 2018-145940, filed Aug. 2, 2018, the entire contents of which are incorporated herein by reference.

What is claimed is:

1. An indoor position estimation apparatus comprising:
at least one memory configured to store one or more instructions; and
at least one processor configured to execute the one or more instructions to:
acquire a target magnetic pattern indicating a result obtained by repeatedly measuring an indoor magnetic field by a position estimation target including a magnetic sensor;
extract predetermined frequency components from the target magnetic pattern; and
obtain an estimation result of an indoor position of the position estimation target by inputting data on the extracted frequency components into an estimation model obtained by machine learning.

2. The indoor position estimation apparatus according to claim 1,
wherein the processor is further configured to execute the one or more instructions to:
acquire a reference magnetic pattern indicating a result obtained by repeatedly measuring a magnetic field by a reference data collection apparatus including a magnetic sensor while the reference data collection apparatus is moving in an indoor area; and
extract, from the reference magnetic pattern, an interest magnetic pattern corresponding to the predetermined frequency components and generates machine learning training data for generating the estimation model based on the interest magnetic pattern,
wherein, in the reference magnetic pattern, a measurement position is associated with each measured magnetic field.

3. The indoor position estimation apparatus according to claim 2,
wherein the processor is further configured to execute the one or more instructions to cut out, from the interest magnetic pattern, a learning pattern indicating a partial transition of a transition of the measured magnetic field indicated by the interest magnetic pattern, and generate the training data assigned to data indicating the learning pattern or a feature of the learning pattern by using, as a label, position information indicating an indoor position at which the magnetic field is measured at a last timing in the partial transition.

4. The indoor position estimation apparatus according to claim 3,
wherein the processor is further configured to execute the one or more instructions to cut out, from the interest magnetic pattern, a plurality of the learning patterns having different lengths.

5. The indoor position estimation apparatus according to claim 3,
wherein the processor is further configured to execute the one or more instructions to divide an indoor area into a plurality of areas, assigns, as the label, identification information for identifying the areas to the data indicating the learning pattern or the feature of the learning pattern, and cut out, from the interest magnetic pattern, the plurality of learning patterns in which measurement positions of the magnetic field measured at a last timing in the partial transition are different positions in a first area of the areas.

6. The indoor position estimation apparatus according to claim 2,
wherein the processor is further configured to execute the one or more instructions to generate the estimation model based on the training data.

7. An indoor position estimation method executed by a computer, the method comprising:
acquiring a target magnetic pattern indicating a result obtained by repeatedly measuring an indoor magnetic field by a position estimation target including a magnetic sensor;
extracting predetermined frequency components from the target magnetic pattern; and
obtaining an estimation result of an indoor position of the position estimation target by inputting data on the extracted frequency components into an estimation model obtained by machine learning.

8. A non-transitory storage medium storing a program causing a computer to:
acquire a target magnetic pattern indicating a result obtained by repeatedly measuring an indoor magnetic field by a position estimation target including a magnetic sensor;
extract predetermined frequency components from the target magnetic pattern; and
obtain an estimation result of an indoor position of the position estimation target by inputting data on the extracted frequency components into an estimation model obtained by machine learning.

9. A user terminal comprising:
at least one memory configured to store one or more instructions; and
at least one processor configured to execute the one or more instructions to:
measure an indoor magnetic field;
acquire a target magnetic pattern indicating a result measured by the magnetic sensor; and
transmit the target magnetic pattern to an indoor position estimation apparatus that estimates a position of the user terminal in an indoor area based on predetermined frequency components included in the target magnetic pattern.

10. An indoor position estimation apparatus comprising:
at least one memory configured to store one or more instructions; and
at least one processor configured to execute the one or more instructions to:
acquire a target magnetic pattern indicating a result obtained by repeatedly measuring an indoor magnetic field by a position estimation target including a magnetic sensor;
extract predetermined frequency components from the target magnetic pattern; and
obtain an estimation result of an indoor position of the position estimation target based on the extracted frequency components.
